(19) United States
(12) Patent Application Publication
(10) Pub. No.: US 2006/0000500 A1
(43) Pub. Date: Jan. 5, 2006

(54) Thermoelectric module

(76) Inventors: Ioan Sauciuc, Phoenix, AZ (US); Gregory M. Chrysler, Chandler, AZ (US)

Correspondence Address: Arlen M. Hartounian;BLAKELY, SOKOLOFF, TAYLOR & ZAFMAN LLP, Seventh Floor, 12400 Wilshire Boulevard, Los Angeles, CA, 90025, US

(21) Appl. No.: 10/882,548

(22) Filed: Jun. 30, 2004

(51) Int. Cl. H01L 35/00; H01L 37/00; H01L 35/34; H01L 35/28; H01L 21/44

(52) U.S. Cl. 136/201; 136/212

(57) ABSTRACT

According to an embodiment of the invention, a thermoelectric module (TEM) is formed between a first and a second thermally conductive device. A first dielectric layer is deposited over the first thermally conductive device, and interconnects are formed over the dielectric layer. Solder patches are then printed over the interconnects. A second dielectric layer is deposited over the second thermally conductive device. Interconnects and solder patches are deposited over the second dielectric layer. Alternating p- and n-type semiconductor elements are then placed over the patches over the first dielectric layer. The second thermally conductive device is then placed over the first device, and the solder is reflowed.

### FIELD OF THE INVENTION

The invention generally relates to heat management in electronic devices and specifically relates to a thermoelectric module for removing heat from a semiconductor device.

### BACKGROUND

Integrated circuits (ICs) such as microprocessors are becoming increasingly powerful over time. The increase in power comes from more transistors that are more densely packaged. The result is that more heat is generated by the ICs, and cooling devices are needed to remove the heat to ensure that ICs will operate reliably.

FIG. 1 illustrates a thermoelectric module (TEM). The TEM 100 operates based on a principle known as the Peltier effect. When a current passes through the junction of two different types of conductors, it results in a temperature change. A TEM is a refrigerator that uses the Peltier effect. When the current is applied to the TEM 100, one side of the TEM 100 is cooled, while heat is driven to the other side. The TEM 100 can therefore be used to cool integrated circuits (ICs) such as high-powered microprocessors by drawing heat away from the IC.

The TEM 100 includes several doped semiconductor elements 102 and 104 sandwiched in between two stiff ceramic plates 106. The doped semiconductor elements include both p-type elements 102 and n-type elements 104. P-type elements 102 have a deficiency of electrons, and n-type elements 104 have an excess of electrons. The elements 102 and 104 are connected in series through layers of solder and copper between the elements 102 and 104 and the ceramic plates 106. The several elements 102 and 104 form several junctions of dissimilar conductors, creating the Peltier effect when a current is applied to the TEM 100.

The TEM 100 is assembled as a unit. The ceramic plates 106 are used to provide rigidity for the TEM 100, since the elements 102 and 104 are not attached to each other. The ceramic plates 106 are typically 0.5-1 mm thick. The TEM 100 is typically assembled and then integrated into a larger cooling system.

FIG. 1B illustrates a cooling system 150 using the TEM 100. An IC 152, such as a microprocessor, has a high operating temperature and requires heat removal. Mounted on top of the IC 152 is a vapor chamber 154, which provides a uniform temperature at the cold side 156 of the TEM 100. A first thermal interface material (TIM) 158, such as a thermal paste or grease, is used to fill gaps and form a junction between the vapor chamber 154 and the TEM 100. A heat sink 160 is mounted over the hot side 162 of the TEM 100. A second TIM 164 fills gaps and forms a junction between the heat sink 160 and the TEM 100. The cooling system 150 draws heat from the IC 152 and into the vapor chamber 154, which evenly distributes the heat over its surface. The TEM 100 draws the heat away from the vapor chamber 154 and into the heat sink 160, where the heat is vented into the atmosphere.

The ceramic plates 106 are thick and have low conductivity. Also, since the ceramic plates 106 are not metal like the elements 102 and 104, the heat sink 160, and the vapor chamber 154, they expand at different rates when heated, potentially leading to stress-induced failures. However, as the TEM 100 is currently constructed, the ceramic plates 106 are needed to provide a rigid backing for the TEM 100 since the TEM is assembled as a single unit. The TIMs 158 and 164 also reduce the thermal conductivity of the cooling system 150 since they are non-metallic.

### BRIEF DESCRIPTION OF THE DRAWINGS

One or more embodiments of the present invention are illustrated by way of example and not limitation in the figures of the accompanying drawings, in which like references indicate similar elements and in which:

FIG. 1 illustrates a TEM;

FIG. 1B illustrates a cooling system using the TEM;

FIGS. 2A and 2B illustrate a cooling system according to an embodiment of the invention;

FIG. 3 is a flowchart describing a process for forming a TEM according to an embodiment of the invention;

FIG. 4A illustrates a dielectric layer deposited over a vapor chamber;

FIG. 4B illustrates a layer deposited over the heat sink;

FIG. 4C illustrates interconnects in the layer;

FIG. 4D illustrates interconnects in the layer;

FIG. 4E illustrates solder patches printed over the interconnects;

FIG. 4F illustrates solder patches printed over the interconnects;

FIG. 4G illustrates the TEC elements placed on the vapor chamber;

FIG. 4H illustrates the heat sink placed over the elements;

FIG. 5A illustrates the pattern for the interconnects over the vapor chamber 210,

FIG. 5B illustrates the pattern for the interconnects over the bottom surface of the heat sink;

FIG. 5C illustrates an overhead view of the solder patches;

FIG. 5D illustrates an overhead view of the solder patches; and

FIG. 5E illustrates an overhead view of the placed elements.

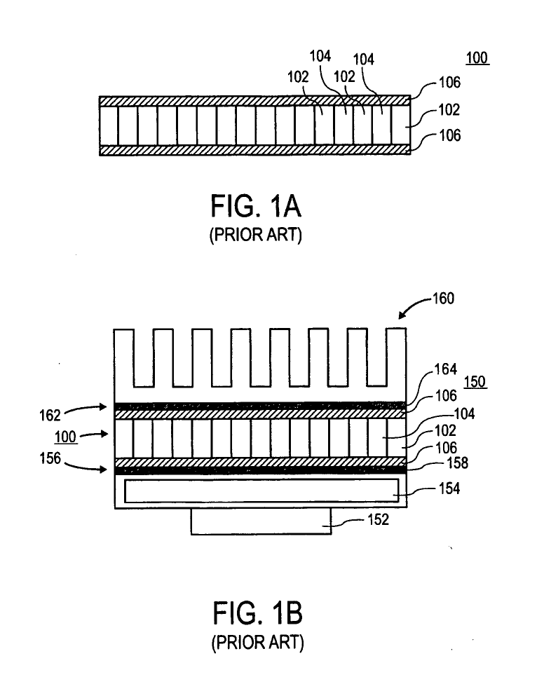

### DETAILED DESCRIPTION

Described herein is a thermoelectric module. Note that in this description, references to “one embodiment” or “an embodiment” mean that the feature being referred to is included in at least one embodiment of the present invention. Further, separate references to “one embodiment” or “an embodiment” in this description do not necessarily refer to the same embodiment; however, such embodiments are also not mutually exclusive unless so stated, and except as will be readily apparent to those skilled in the art from the description. For example, a feature, structure, act, etc. described in one embodiment may also be included in other embodiments. Thus, the present invention can include a variety of combinations and/or integrations of the embodiments described herein.

According to an embodiment of the invention, a thermoelectric module (TEM) is formed by first depositing a dielectric layer, such as an epoxy or enamel, over the surfaces which will envelop the TEM. For example, if a TEM is to be placed between a vapor chamber and a heat sink, an epoxy is spread over a top surface of the vapor chamber and a bottom surface of the heat sink. Interconnects are then patterned over the epoxy. The interconnects form connections between the elements in the TEM. Solder is then patterned on the interconnects, and the individual elements are placed over the solder on one of the surfaces (for example, over the vapor chamber) using a pick and place or other placement method. The other surface (for example, the heat sink) is then placed over the elements, and the assembly is baked in an oven to reflow the solder.

By assembling the TEM in this way, the ceramic plates are no longer needed, since the heat sink and vapor chamber (or other items) provide rigidity for the TEM. Since the ceramic plates are eliminated, thermal conductivity of the cooling system is increased, because ceramics have relatively low conductivity. The incidence of stress-induced failures is also reduced, since there is less of a difference in the conductivity of the materials used and since the epoxies or other dielectrics used are more pliant than ceramics. Further, the dielectric layers replacing the ceramic plates are not as thick, thereby reducing the impact of their lower conductivity. The thermal interface materials (TIMs) are also obviated, leading to their removal and an improvement in thermal conductivity of the entire cooling assembly.

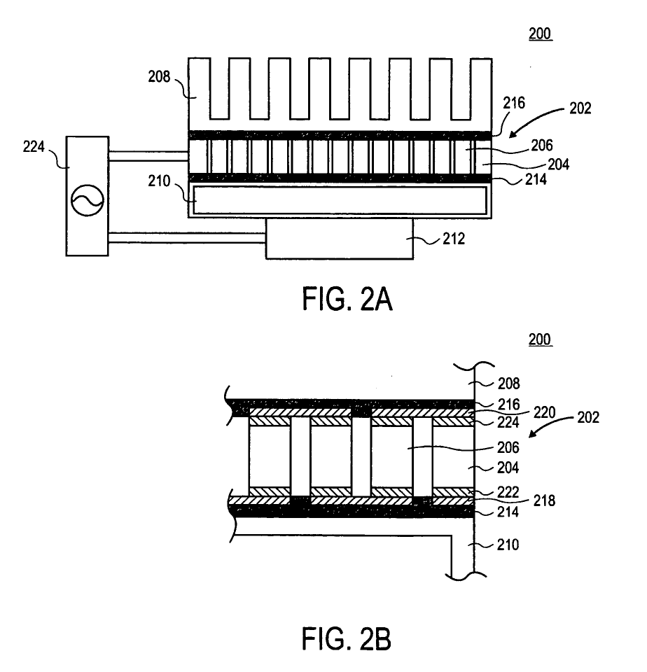

FIGS. 2A and 2B illustrate a cooling system 200 according to an embodiment of the invention. Unlike previous implementations, the TEM 202 is assembled while the entire cooling system 200 is assembled, rather than being assembled separately. The TEM 202 includes several p-type 204 and n-type 206 elements. The TEM is sandwiched between a heat sink 208 and a vapor chamber 210. The cooling system 200 reduces the operating temperature of a device 212. The device 212 may be any device that needs cooling, such as integrated circuits (ICs) including microprocessors, memory chips, chipsets, etc. Thermally conductive devices other than a heat sink 208 or a vapor chamber 210 may also be used. For example, a heat pipe or a fan may be used in place of the heat sink 208, and a solid spreader may be used in place of the vapor chamber 210. A solid spreader, for example, may be less expensive than the vapor chamber 210.

The p-type 204 and n-type 206 elements are doped semiconductors. In one embodiment, the elements 204 and 206 comprise Bisumth Telluride, but in other embodiments they could comprise other materials such as a silver-lead-antimony-terillium alloy. The elements 204 and 206 may be doped using ion implantation or other known techniques. The elements 204 and 206 are alternating p- and n-type semiconductors to produce the Peltier effect.

The elements 204 and 206 are mounted on a dielectric layer 214 and underneath a dielectric layer 216. The layers 214 and 216 are insulating dielectric layers, isolating the elements and the interconnects. The layers 214 and 216 may be any appropriate insulator or dielectric, such as an epoxy, an enamel, or a polyamide. According to one embodiment of the invention, the layers 214 and 216 are less than 100 microns thick. According to another embodiment of the invention, the layer 214 is deposited on a surface of the vapor chamber 210 before the elements 204 and 206 are placed over the vapor chamber 210. According to another embodiment of the invention, the layers 214 and 216 comprise a pliant material that is resistant to stress induced failures caused by the expansion and contraction of metal elements in the cooling system 200.

Several interconnects 218 and 220 electrically couple the elements 204 and 206. The interconnects 218 and 220 may be any conductive material such as copper, and may be placed over as well as in the layers 214 and 216. The thickness of the interconnects 218 and 220 may determined based on the amount of current needed to achieve a desired temperature level. The interconnects 218 could be thinner or thicker than the layers 214 and 216. The elements 204 and 206 are attached to the interconnects 218 and 220 through solder patches 222 and 224. The solder patches 222 and 224 may be any appropriate solder such as a tin or a lead free solder. The solder patches 222 and 224 create a joint between the elements 204 and 206 and the interconnects 218 and 220.

Current is applied to the elements 204 and 206. This results in the Peltier effect which creates a cold side of the TEM near the vapor chamber 210 and a hot side of the TEM 202 near the heat sink 208. A feedback system 224 applies the current to the elements 204 and 206. The feedback system 224 may be controlled by the IC 212, which may change the current fed to the TEM 202 when cooling requirements change.

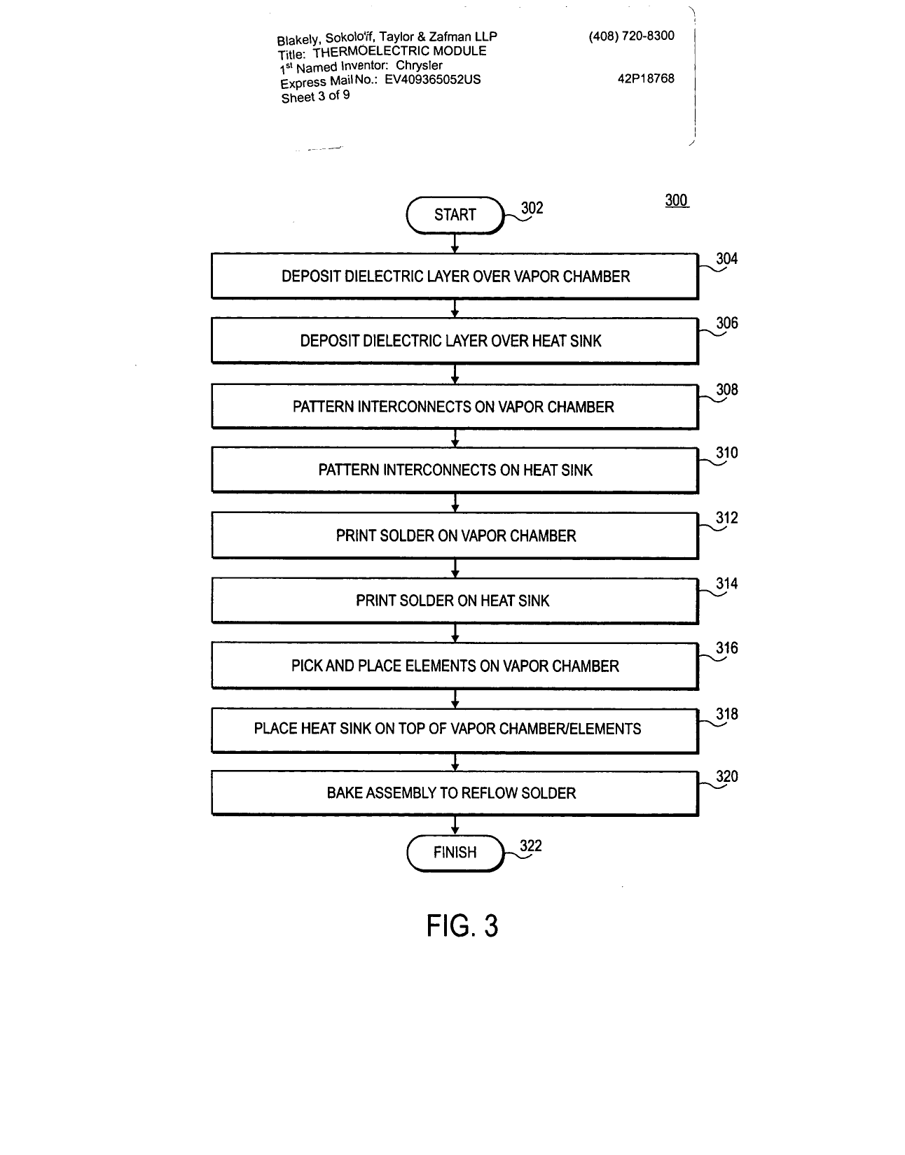

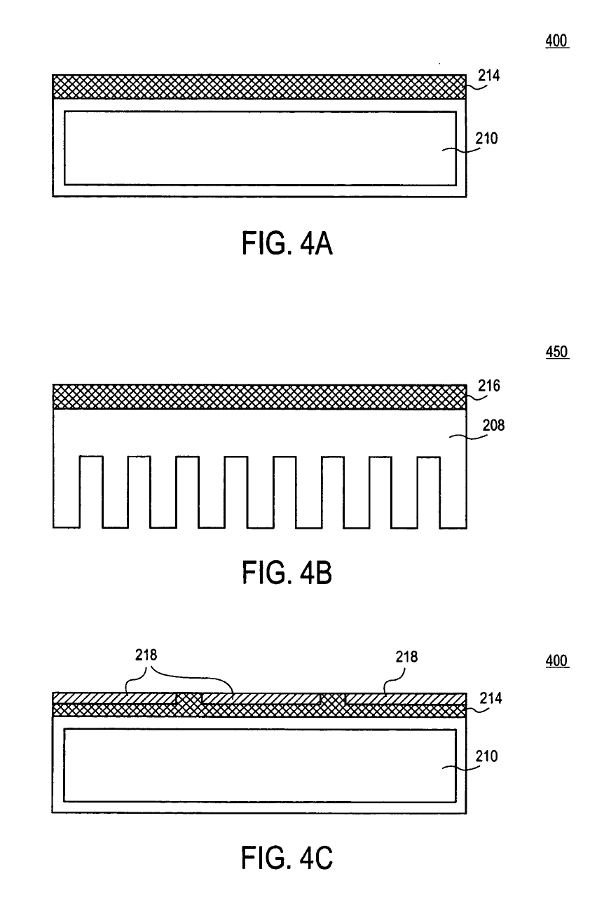

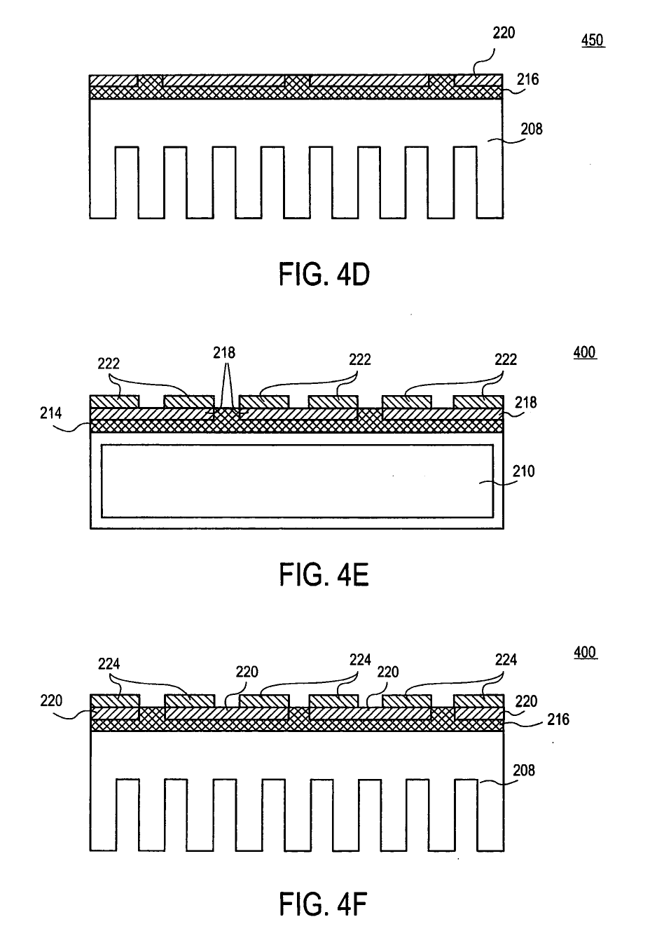

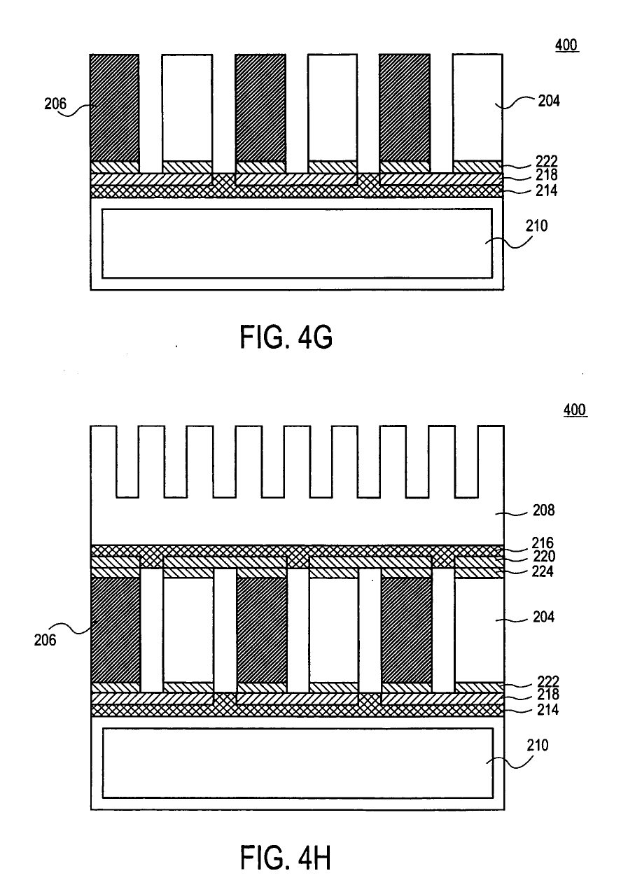

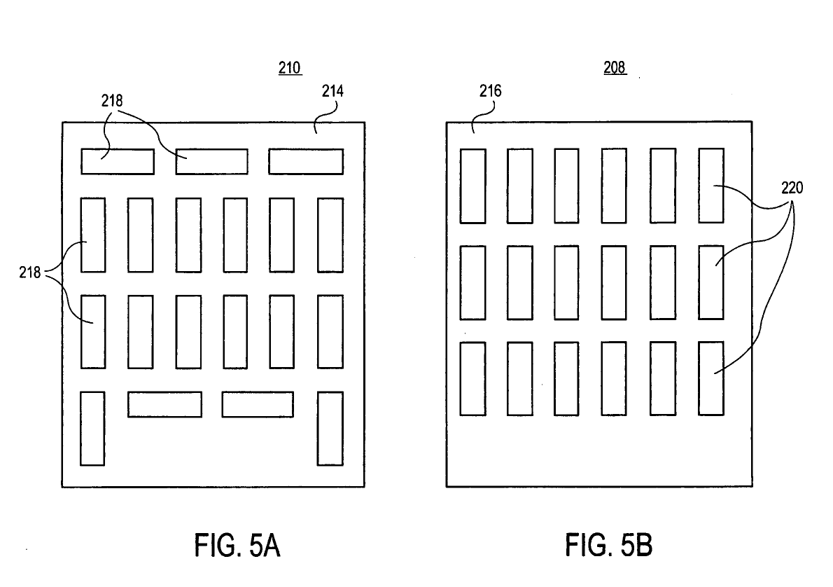

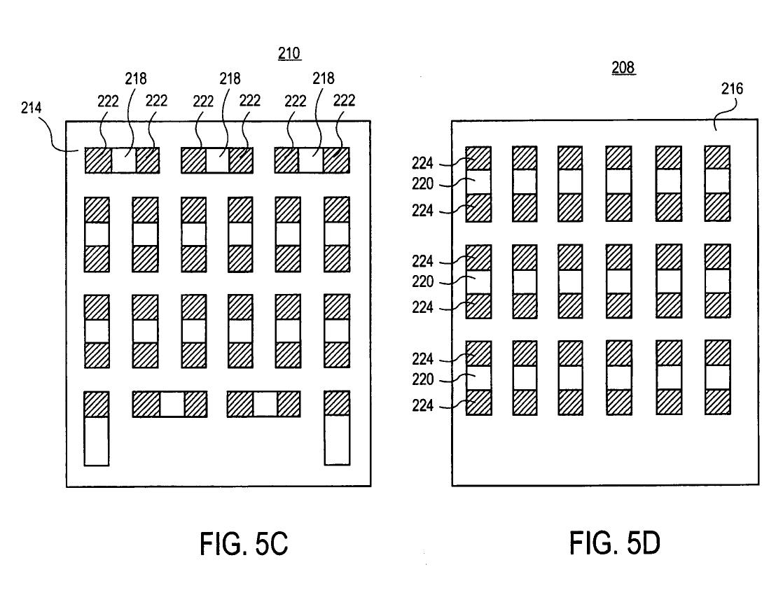

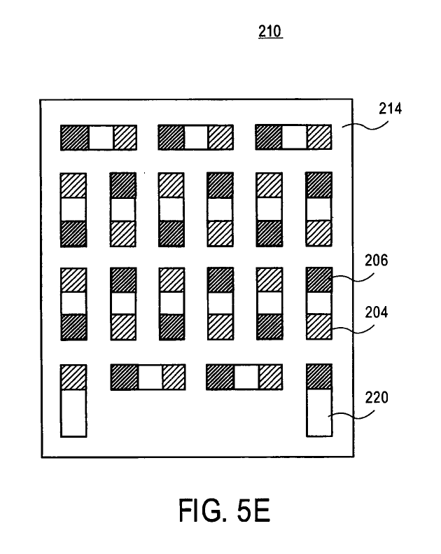

FIG. 3 is a flowchart describing a process 300 for forming a TEM 202 according to an embodiment of the invention. FIGS. 4A-4H illustrate the process described in FIG. 3. FIGS. 5A-5E illustrate interconnect and solder patterns for a TEM 202 according to one embodiment of the invention. FIGS. 4A-H show a cross-sectional view similar to FIGS. 2A and 2B, while FIGS. 5A-E show an overhead view of the interconnect and solder patterns formed on the heat sink 208 and the vapor chamber 210.

The process 300 begins in start block 302. In block 304, the dielectric layer 214 is deposited over the vapor chamber 210. FIG. 4A illustrates a dielectric layer 214 deposited over a vapor chamber 210. The dielectric layer 214 may be an epoxy, an enamel, etc. that is spun or sprayed on. It is understood that other appropriate deposition techniques may be used. After the layer 214 is deposited over the vapor chamber 210, the layer 214 is cured.

In block 306, a dielectric layer 216 is deposited over a bottom surface of the heat sink 208. FIG. 4B illustrates a layer 216 deposited over the heat sink 208. As with the layer 214, the layer 216 may comprise an epoxy, and may be spun or sprayed on. The layer 216 is then cured.

In block 308, interconnects are patterned in the layer 214 deposited on the vapor chamber 210. FIG. 4C illustrates interconnects in the layer 214. The interconnects 218 are patterned and deposited on the dielectric layer 214. According to one embodiment of the invention, a solder paste is deposited over the layer 214, and screen printed to form the pattern. The copper interconnects 218 can then be electrolessly deposited over the solder paste.

Electroless deposition involves first chemically activating the areas to be plated. For example, the remaining solder paste can be activated using an appropriate solution, such as a palladium based activation solution. The vapor chamber 210 is then deposited in a chemical bath. The bath includes copper ions which are chemically attracted to the activated areas, namely the screen printed areas. This way, the interconnects can be formed on the layer 214. The thickness of the interconnects 218 increase the longer the vapor chamber 210 is left in the bath, as is known in the art. It is understood that other conductive materials, such as aluminum, may be used to form the interconnects 218.

In block 310, interconnects are patterned in the layer 216 deposited on the heat sink 208. FIG. 4D illustrates interconnects in the layer 216. The interconnects 220 are patterned and deposited in a manner similar to how they are deposited over the vapor chamber 210.

FIG. 5A illustrates the pattern for the interconnects 218 over the vapor chamber 210. FIG. 5B illustrates the pattern for the interconnects 220 over the bottom surface of the heat sink 208. As can be seen, the patterns of the interconnects 218 over the vapor chamber 210 and the interconnects 220 over the heat sink 208 are complementary. The interconnects 218 and 220 are used to electrically couple the TEM elements 204 and 206. When the interconnects 220 are placed over the interconnects 218, a single path is formed through the elements 204 and 206. Certain of the interconnects 218 or 220 may also be used to connect with the feedback system 224 to provide the current for the TEM 202.

Returning to FIG. 3, in block 312, solder is printed over the interconnects 218 on the vapor chamber 210. FIG. 4E illustrates solder patches 222 printed over the interconnects 218. FIG. 5C illustrates an overhead view of the solder patches 222. Again, the thickness of the solder patches 222 is exaggerated to improve clarity. The TEC elements 204 and 206 will be placed over the solder patches 222. The solder patches 222 provide a junction between the interconnects 218 and the TEC elements 204 and 206. The solder patches 222 may be screen printed on the interconnects 218. As can be seen, the solder patches 222 cover only the ends of the interconnects 218. By printing the solder patches 222 in this way, the TEC elements 204 and 206 can be spaced out to effectively insulate them from each other. The exposed patch of the interconnects 218 provides a connection between adjacent elements 204 and 206 where it is appropriate.

In block 314, solder is printed over the interconnects 220 on the heat sink 208. FIG. 4F illustrates solder patches 224 printed over the interconnects 220. FIG. 5D illustrates an overhead view of the solder patches 224. The solder patches 224 are similar to the solder patches 222 described above. The solder patches 224 may also be screen printed on the interconnects 220.

In block 316, the TEC elements 204 and 206 are placed over the solder patches 222 on the vapor chamber 210. FIG. 4G illustrates the TEC elements 204 and 206 placed on the vapor chamber 210. The p-type 204 and n-type 206 TEC elements can be placed over the solder patches 222 using a pick and place technique. FIG. 5E illustrates an overhead view of the placed elements 204 and 206. As can be seen, the elements 204 and 206 are placed over the solder patches 222. The solder patches 222 may provide an adhesive force sufficient to hold the elements 204 and 206 in place until the solder can be reflowed. After the final assembly of the system 200 is complete, the assembly is baked to reflow the solder 222, creating a permanent junction.

In block 318, the heat sink 208 is inverted and placed over the vapor chamber 210 and the elements 204 and 206. FIG. 4H illustrates the heat sink 208 placed over the elements 204 and 206. The heat sink 208 is placed so that the solder patches 224 are aligned over the elements 204 and 206. In block 320, the entire assembly 400 is baked in an oven at a temperature sufficient to reflow the solder 222 and 224. This forms permanent junctions between the interconnects 218 and 220 and the elements 204 and 206. In block 322, the process 300 is finished.

It is understood that although the process 300 describes placing the elements 204 and 206 on the vapor chamber 210, the elements may also be placed on the heat sink 208. Further, the TEM 202 may be formed between other rigid devices not described herein.

Since the TEM 202 is formed over the heat sink 208 and the vapor chamber 210, rather than preformed and placed between the heat sink 208 and the vapor chamber 210, ceramic plates and TIMs are not needed. As a result, the TEM 202 has better thermal conductivity. The TEM 202 also is more resistant to stresses introduced because of the difference in the coefficient of expansion of the various materials.

This invention has been described with reference to specific exemplary embodiments thereof. It will, however, be evident to persons having the benefit of this disclosure that various modifications changes may be made to these embodiments without departing from the broader spirit and scope of the invention. The specification and drawings are accordingly to be regarded in an illustrative rather than in a restrictive sense.

What is claimed is:

1. A method for forming a thermoelectric module (TEM) comprising:
depositing a first dielectric layer over a first thermally conductive device;
depositing a second dielectric layer over a second thermally conductive device;
placing thermoelectric elements over the first dielectric layer; and
placing the second thermally conductive element over the thermoelectric elements.

2. The method of claim 1, further comprising:
forming interconnects over the first and second dielectric layers and connecting the interconnects to the thermoelectric elements.

3. The method of claim 1, wherein depositing a first dielectric layer comprises spinning on a first enamel layer and wherein depositing a second dielectric layer comprises spinning on a second enamel layer.

4. The method of claim 1, wherein depositing a first dielectric layer comprises spinning on a first epoxy layer and wherein depositing a second dielectric layer comprises spinning on a second epoxy layer.

5. The method of claim 2, further comprising:
applying a current to the interconnects to activate the TEM.

6. The method of claim 1, wherein the thermoelectric elements comprise doped semiconductor elements.

7. The method of claim 6, wherein the doped semiconductor elements comprise alternating p-type elements and n-type elements.

8. The method of claim 2, further comprising:
screen printing solder patches over the interconnects.

9. The method of claim 1, wherein depositing a first dielectric layer comprises spraying on a first enamel layer and wherein depositing a second dielectric layer comprises spraying on a second enamel layer.

10. The method of claim 1, wherein depositing a first dielectric layer comprises screen printing a first enamel layer and wherein depositing a second dielectric layer comprises screen printing a second enamel layer.

11. A thermoelectric module (TEM) comprising:
a first thermally conductive device including a first pliant dielectric layer;
a second thermally conductive device including a second pliant dielectric layer;
a first thermoelectric element between the first and second dielectric layers; and
a second thermoelectric element coupled to the first thermoelectric element and between the first and second dielectric layers, the first thermoelectric element is different from the second thermoelectric element.

12. The TEM of claim 11, wherein the first thermally conductive device is a heat sink and wherein the second thermally conductive device is a vapor chamber.

13. The TEM of claim 11, wherein the first thermoelectric element is a p-type element, and wherein the second thermoelectric is an n-type element.

14. The TEM of claim 11, wherein the first and second dielectric layers comprise an epoxy.

15. The TEM of claim 11, wherein the first and second dielectric layers comprise an enamel.

16. The TEM of claim 13, further comprising:
a first set of interconnects over the first dielectric layer and a second set of interconnects over the second dielectric layer to couple the p-type element and the n-type element.

17. The TEM of claim 16, further comprising:
a set of solder patches between the interconnects and the p-type and n-type elements.

18. The TEM of claim 11, wherein the second thermally conductive device is a solid spreader.

19. A method for forming a thermoelectric element (TEM) comprising:
forming a first dielectric layer over vapor chamber;
forming a second dielectric layer over a heat sink;
forming a first set of interconnects over the first dielectric layer and forming a second set of interconnects over the second dielectric layer;
placing a first set of thermoelectric elements and a second set of thermoelectric elements different from the first set of thermoelectric elements over the first set of interconnects using a pick and place technique; and
placing the heat sink over the vapor chamber and aligning the second set of interconnects with the first and second sets of thermoelectric elements.

20. The method of claim 19, further comprising:
screen printing solder patches between the interconnects and the thermoelectric elements.

21. The method of claim 20, further comprising:
reflowing the solder patches.

22. The method of claim 19, wherein the first and second dielectric layers comprise an epoxy.

23. The method of claim 19, wherein the first and second dielectric layers comprise an enamel.

24. The method of claim 19, wherein the first set of thermoelectric elements comprises p-type elements and wherein the second set of thermoelectric elements comprise n-type elements.
